(19) United States
(12) Patent Application Publication
(10) Pub. No.: US 2005/0168138 A1
(43) Pub. Date: Aug. 4, 2005

(54) Organic light emitting display device

(76) Inventors: Masaaki Okunaka, Chiba (JP); Issei Takemoto, Chiba (JP)

Correspondence Address: ANTONELLI, TERRY, STOUT & KRAUS, LLP, 1300 NORTH SEVENTEENTH STREET, SUITE 1800, ARLINGTON, VA, 22209-3873, US

(21) Appl. No.: 11/017,727

(22) Filed: Dec. 22, 2004

(30) Foreign Application Priority Data
Dec. 25, 2003 (JP) 2003-429411

(51) Int. Cl. H01J 1/62; H01J 63/04

(52) U.S. Cl. 313/504

(57) ABSTRACT

The present invention provides a display device which can realize the easy quality control of a display panel thus enhancing the quality and the reliability of the manufacturing of the display device. To achieve the object, the display device includes a light transmitting glass substrate SUB1 which has a display region AR formed of a pixel circuit in which a large number of display pixels SP each of which is constituted of a light emitting element and an active element are arranged in a matrix array on a main surface thereof; and a sealing glass substrate SUB2 which covers the main surface of the light transmitting glass substrate SUB1 and is hermetically sealed to a peripheral portion of the light transmitting glass substrate SUB1 with a sealing agent SEL therebetween. A dummy pixel DP which is constituted of a light emitting element and a passive element is arranged outside the display region AR on the main surface of the light transmitting glass substrate SUB1. The display pixels SP and the dummy pixel DP are formed by sequentially stacking anodes AD, organic multilayered films ELM and cathodes KD on the main surface of the light transmitting glass substrate SUB1 respectively. In the dummy pixel DP, the organic multilayered film ELM is exposed by removing at least a portion of the cathode KD, and an electric current path is formed between a remaining other portion of the cathode KD and the anode AD.

### CROSS-REFERENCE TO RELATED APPLICATIONS

The disclosure of Japanese Patent Application No. 2003-429411 filed on Dec. 25, 2003 including the specification, drawings and abstract is incorporated herein by reference in its entirety.

### BACKGROUND OF THE INVENTION

1. Field of the Invention

The present invention relates to a display device, and more particularly to an organic EL display device using an organic light emitting element and having dummy pixels located in the outside of a display region.

2. Description of the Related Art

Recently, as a flat panel type display device, a liquid crystal display device (LCD), a plasma display device (PDP), a field emission type display device (FED) and an organic EL display device (OLED) and the like have been practically used or in the stage of researches for practical use. Among these display devices, the organic EL display device is an extremely promising display device as a representative of a thin and self-light emitting type display device and as a future display device. The organic EL display device is classified into a so-called bottom emission type organic EL display device and a so-called top emission type organic EL display device.

In the bottom emission type organic EL display device, an organic light emitting element has a light emitting structure which is formed by sequentially stacking a light transmitting electrode (made of ITO or the like) which constitutes one electrode (a first electrode), an organic multilayered film including an organic light emitting layer which emits light when an electric field is applied thereto, and a light reflecting metal electrode (Al or the like) which constitutes another electrode (a second electrode) on an insulating substrate which is preferably formed of a glass substrate. A large number of these organic light emitting elements are arranged in a matrix array, and another substrate which is referred to as a sealing cap (also called as a sealing can) is provided in a state that the sealing cap covers the stacked structure thus shielding the above-mentioned light emitting structure from the external atmosphere.

Then, by adopting the light transmitting electrode as an anode and the light reflecting metal electrode as a cathode, for example, and by applying an electric field between both electrodes, carriers (electrons and positive holes) are injected in the organic multilayered film and hence, the organic multilayered film emits light. Then, the emitted light is radiated to the outside from the glass substrate side.

On the other hand, the top emission type organic EL display device is configured as follows. That is, by adopting the above-mentioned one electrode as a metal electrode made of Al or the like having the light reflecting property and the above mentioned another electrode as the light transmitting electrode formed of ITO or the like and by applying an electric field between both electrodes, the organic multilayered film emits light and the emitted light is radiated from the above-mentioned another electrode side. In this top emission type organic EL display device, as the sealing cap used in the bottom emission type organic EL display device, a light transmitting plate member which is preferably made of a glass plate is used.

In the organic EL display device which uses such an organic light emitting element, an insulating substrate which forms the organic light emitting element on a main surface thereof and the sealing cap which protects the organic light emitting element are arranged to face each other, a sealing material is applied to peripheral portions of both substrates and is cured thus laminating both substrates in a state that the inside of both substrates is insulated and sealed from the external atmosphere.

Further, the organic EL display device having such a constitution, at the time of manufacturing the organic light emitting element, the organic multilayered film absorbs moisture and other gas components such as oxygen and the like in air and hence, the light emitting property is deteriorated in a short time. Accordingly, at the time of manufacturing the organic light emitting element, for the purpose of performing the dehumidification of the inside of the sealed space, a desiccant is usually mounted in the inside of the sealing cap with respect to the bottom emission type organic EL display device and in the inside of the insulating substrate with respect to the top emission type organic EL display device.

Further, in the organic EL display device having such a constitution, the cathode and the organic multilayered film exhibit the low resistance against water, oxygen, heat or ultraviolet rays. Particularly, since water gives a large influence on the organic multilayered film, obstructs the light emission, and becomes the largest cause of the occurrence of defects which are referred to as so-called dark spots which constitute non-light emitting portions. Accordingly, to realize the organic EL display device having the high reliability, it is necessary to prevent the intrusion of these elements into the cathode and the organic multilayered film.

Further, to prevent the intrusion of these elements of the defect, at the time of manufacturing the organic EL display device, a dried inactive gas is filled in the inside of the sealing space sealed by the sealing cap. Although it is necessary to maintain this state even after the organic EL display device is formed into a panel, here considered is a case in which water molecules infiltrate into the sealed space from the outside by way of the sealing material due to the use of the organic EL display device for a long period. Accordingly, to always maintain the proper dried state at the time of sealing in the inside of the sealed space by absorbing the water molecules which intrude from the outside after the organic EL display device is formed into the panel, a desiccant is mounted in the inside of the sealing cap.

As the structure which adopts the countermeasure to cope with the above-mentioned intrusion of water molecules, the JP-A-2003-157970 discloses the structure in which an indicator which changes colors when the water molecules are absorbed in a region other than a display region is arranged on a substrate, and by detecting a moisture content intruded into the inside of the sealed space, a lifetime of the organic EL display device can be predicted to some extent in the stage of shipping the organic EL display device from a factory.

### SUMMARY OF THE INVENTION

However, in the organic EL display device having such a constitution, with respect to inspection methods of favorable/bad adhesiveness of the sealing structure in a package, a measurement and inspection of a width and a height of the sealing member, an inspection of the presence or non-presence of voids, an inspection of the presence or non-presence of leaked portions, and an inspection of the presence or non-presence of peeled portions of the sealing member also rely on the inspection using a microscope. Accordingly, there has been a drawback that an operation (an inspection step) which is required for all of these inspection items becomes extremely cumbersome.

Further, in this inspection method, there has been another drawback that it is impossible to directly determine whether the moisture concentration in the inside of the package is at a level which causes problems on the organic light emitting element or not. That is, there exists a large possibility that even when small leak path is present in the sealing structure, such a leak path cannot be found out. For example, to find out such a leak path, there have been drawbacks that an extremely expensive inspection facility becomes necessary and, at the same time, the inspection requires long inspection steps and hence, a heavy inspection cost is necessary.

Accordingly, the present invention has been made to overcome the drawbacks of the related art and it is an object of the present invention to provide a display device which is capable of directly and easily inspecting the occurrence of dark spots attributed to the intrusion of moisture and other gas components such as oxygen in air whereby the quality control of a display panel can be realized easily and the quality and the reliability can be enhanced.

Further, it is another object of the present invention to provide a display device which enables the direct inspection of the occurrence of dark spots attributed to the intrusion of moisture and other gas components such as oxygen in air whereby an expensive inspection facility is no more necessary, a leak inspection without fails can be realized, the number of inspection steps can be remarkably reduced, and the high productivity can be realized at a low cost.

According to the present invention, an organic EL display device includes a substrate and an organic EL elements formed on the substrate. And each of the organic EL elements has a first electrode which is formed on the substrate, multilayered film including organic light emitting layer which is formed on the first electrode, and second electrode which is formed on the multilayered film. And the organic EL display being hermetically sealed. Furthermore, a part of the organic EL elements, whose second electrode has an opening portion or the multiplayer which has the portion overlapped to the first electrode and not overlapped to the second electrode is formed in the outside of the display region.

By allowing the organic light emitting layers to emit light in such a state, it is possible to use the organic light emitting layers as an indicator of the moisture concentration in the inside of a package, that is, an environment of pixels which are used in an actual display and hence, the above-mentioned object can be achieved.

Further, according to the display device of the present invention, it is possible to determine whether the sealing structure of the display panel is defective or non-defective based on the light emission level, that is, the brightness of the organic emitting layers and hence, the expensive inspection facility becomes no more necessary, and the inspection cost and the inspection time can be largely reduced and shortened.

In the same manner, due to the following constitutions, exposed portions of second pixels from the multilayered film are allowed to function as an indicator of the moisture concentration in the inside of the package and hence, it is possible to overcome the drawbacks of the related art.

A. The display device includes a first substrate which has a display region formed of a pixel circuit in which a large number of first pixels each of which is constituted of a light emitting element and an active element are arranged in a matrix array on a main surface thereof, and a second substrate which covers the main surface of the first substrate and is hermetically sealed to a peripheral portion of the first substrate with a sealing agent therebetween, wherein at least one second pixel which is constituted of a light emitting element and a passive element is arranged outside the display region on the main surface of the first substrate, the first pixels and the second pixel are formed by sequentially stacking a first electrode, a light emitting layer or a multilayered film including the light emitting layer and a second electrode on the main surface of the first substrate respectively, and in the second pixel, the multilayered film is exposed by removing at least a portion of the second electrode, and an electric current path is formed between a remaining portion of the second electrode and the first electrode.

In the above-mentioned constitution A, the present invention is also characterized by following constitutions B to G.

B. An area removed by the removal of the portion of the second electrode is within a range of 0.01% to 95% of an area of the second electrode.

C. A shape which is formed after removing the portion of the second electrode has a rectangular shape.

D. A portion which is formed by removing the portion of the second electrode is made to have a shape which is formed by removing the portion with the radiation of YAG pulse laser beams.

E. A portion which is formed by removing the portion of the second electrode is formed into a second-electrode non-forming portion.

F. A plurality of first pixels and second pixel are individually driven.

G. A large number of first pixels in the inside of the display region AR are driven by the active matrix driving and the second pixel is driven by the passive matrix driving.

Here, it is needless to say that the present invention is not limited to the above-mentioned respective constitutions and the constitutions described in embodiments which will be explained later and various modifications can be made without departing from the technical concept of the present invention.

### BRIEF DESCRIPTION OF THE DRAWINGS

FIG. 1 is an explanatory view of a mechanism of the occurrence of dark spots;

FIG. 2 is a schematic view for explaining the overall structure of an organic EL display device;

FIG. 3 is a cross-sectional view for explaining one constitutional example of an organic light emitting element;

FIG. 4 is an enlarged plan view of an essential part of the organic EL display device;

FIG. 5 is a plan view showing a leak path;

FIG. 6 is a view showing a state in which a cathode non-forming portion is formed by removing a portion of the cathode by laser radiation;

FIG. 7 is a view showing a state in which a size of a non-light-emitting area becomes larger than a size of the cathode non-forming region attributed to the incompleteness of the sealing structure of a package;

FIG. 8 is a plan view showing a shape of the cathode non-forming portion of the dummy pixel; and

FIG. 9 is a plan view showing a shape of the cathode non-forming portion of the dummy pixel.

### DETAILED DESCRIPTION OF THE INVENTION

Hereinafter, specific embodiments of the present invention are explained in detail in conjunction with drawings which show the embodiments.

### Embodiment 1

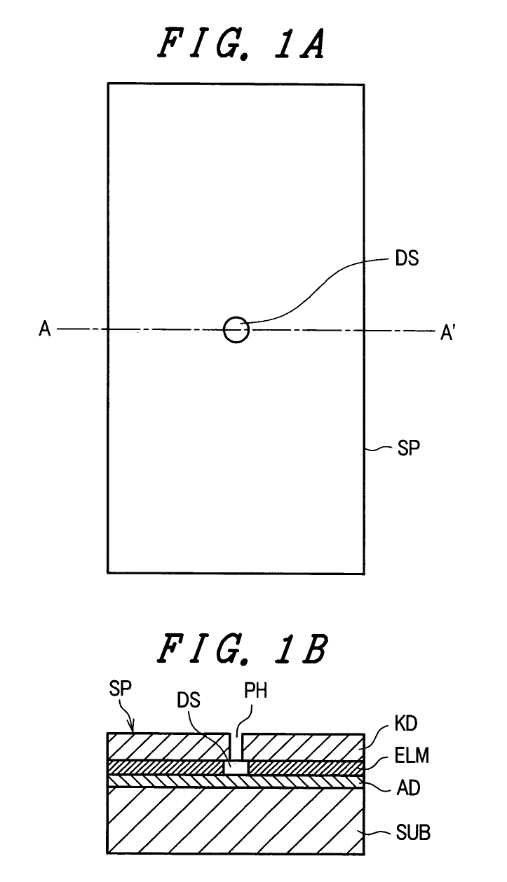

FIG. 1A and FIG. 1B are views for explaining a mechanism of occurrence of dark spots for facilitating the understanding of a gist of the present invention before explaining an embodiment 1 of a display device according to the present invention, wherein FIG. 1A is a plan view of a display pixel SP which is constituted of an organic light emitting element for forming an organic EL display device and FIG. 1B is a cross-sectional view taken along a line A-A′ in FIG. 1A.

In FIG. 1A and FIG. 1B, the bottom emission type organic light emitting element is constituted of a light emitting mechanism which is formed by sequentially stacking an anode AD which is made of ITO or the like, for example, an organic multilayered film ELM which emits light by applying an electric field thereto, a cathode KD which is made of lithium fluoride, aluminum or the like having light reflecting property on a light transmitting substrate SUB which is preferably formed of a glass substrate. A plurality of these organic light emitting elements (display pixels SP) are arranged in a matrix array and a sealing cap not shown in the drawing is sealed to cover these organic light emitting elements using a sealing agent thus forming a package to shield the organic light emitting elements from the ambient atmosphere.

The organic light emitting element which has such a constitution readily stops the light emission when the organic multilayered film ELM is exposed to moisture or oxygen. Further, the cathode KD possesses a passivation action of moisture as well as an original action as the cathode. However, when the moisture concentration in the inside of the package becomes high and a pin hole PH is present in the cathode KD, as shown in FIG. 1A, a non-light-emitting defective portion which is referred to as a dark spot DS occurs in the inside of the light emitting area of the display pixel SP.

The dark spot DS occurs in accordance with a process in which the moisture intrudes the organic multilayered film ELM from the pin hole PH formed in the cathode KD so that an organic material is degenerated and does not emit light. When the pin hole PH is not present in the cathode KD, for example, even when the moisture concentration in the inside of the package is high, for example, the dark spot DS hardly occurs. The gist of the present invention lies in the positive utilization of this generation mechanism of the dark spot DS for the defective/or non-defective determination inspection of the package.

Next, the embodiment 1 of the display device to which the present invention is applied is explained in conjunction with the drawings.

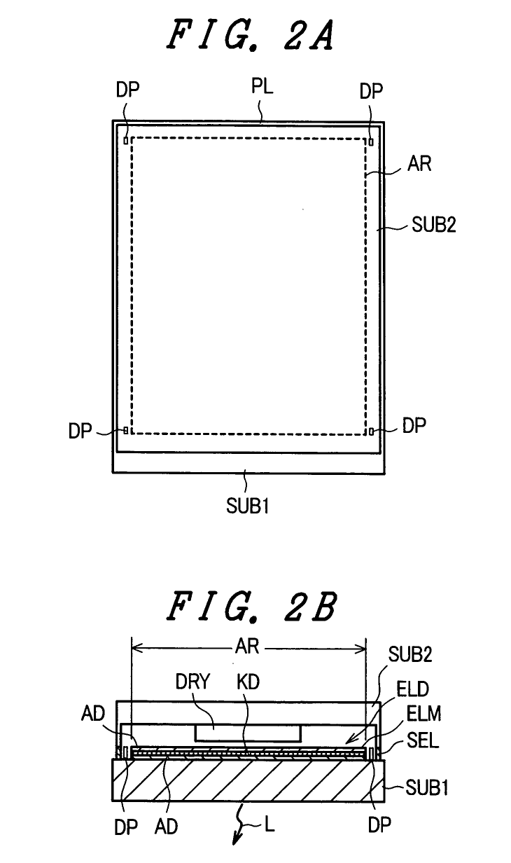

FIG. 2 is a view for schematically explaining the total structure of an organic EL display device which constitutes the display device of the present invention, wherein FIG. 2A is a plan view and FIG. 2B is a cross-sectional view. FIG. 2B shows an organic light emitting element formed of the stacked structure which is constituted of anodes AD formed on a light transmitting glass substrate SUB1, organic multilayered films ELM which are formed on the anodes AD, and cathodes KD formed on the organic multilayered films ELM.

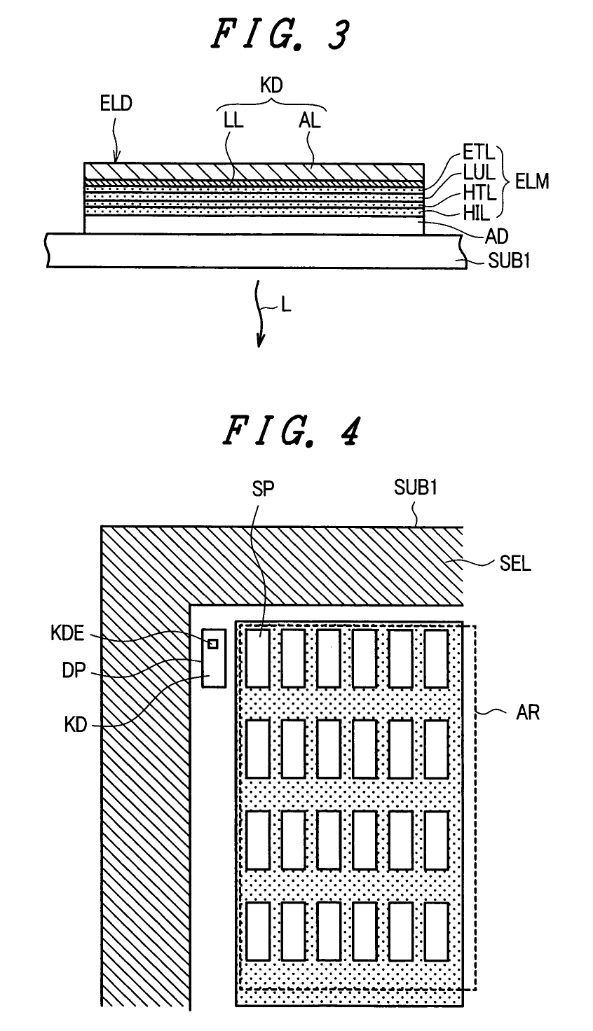

In FIG. 2, the organic EL display device is configured as follows. On an inner surface which constitutes a main surface of the light-transmitting glass substrate SUB1, a large number of the organic light emitting elements ELD having the constitution shown in FIG. 3 are formed in a matrix array. Here, FIG. 3 is an enlarged cross sectional view of an essential part of the organic light emitting elements ELD. The organic light emitting elements ELD include a large number of thin film transistors as active elements for selecting and driving pixel and pixel circuits formed of holding capacitance for respective pixels, wherein these large number of display pixels form a display region AR. Further, outside the display region AR and inside a sealing agent described later (not shown in the drawing), a drive circuit region where a drive circuit is formed is arranged.

In the organic EL display device which is formed using such an organic light emitting element ELD, for enhancing the power efficiency, the active matrix driving which uses the thin film transistor in the display pixel as a switching element is effective. Here, the active element is not limited to the thin film transistor.

In this organic light emitting element ELD, as shown in FIG. 3, the anode AD which is formed of a transparent conductive film (thin film) made of ITO (In—Ti—O) or the like is formed on the light transmitting glass substrate SUB1, and an organic multilayered film ELM which constitutes the organic light element structure of the organic light emitting element ELD is formed on the anode AD. The organic multilayered film ELM is configured such that a positive hole injection layer HIL, a positive hole transport layer HTL, an organic EL light emitting layer LUL and an electron transport layer ETL which are formed of a thin film made of an organic material are sequentially stacked from the anode AD side. Further, on the electron transport layer ETL, the cathode KD which constitutes a light emission control electrode which is formed of a lithium fluoride (LiF) layer LL which constitutes a first layer and an aluminum (Al) layer AL which constitutes a second layer and is formed on the lithium fluoride layer LL is formed. Here, the anode AD, the organic multi-layered film ELM and the cathode KD are formed by a vapor deposition method which uses a mask, for example.

In the organic light emitting element ELD having such a constitution, light is emitted from the organic EL light emitting layer LUL when a given voltage is applied between the cathode KD and the anode AD, positive holes are transferred from the positive hole injection layer HIL to the organic EL light emitting layer LUL and electrons are injected into the organic light emitting element ELD from the electron transport layer ETL. The organic EL light emitting layer LUL emits light due to such transport of the positive holes and the injection of the electrons and radiates the light as an emitting light L to the outside from the light transmitting glass substrate SUB.

Further, at four corners outside the display region AR which is formed by arranging the large number of organic light emitting elements ELD in a matrix array on the main surface of the light transmitting glass substrate SUB1, dummy elements DP each of which is constituted of an organic light emitting element having the exactly same constitution as the organic light emitting element ELD as shown in an enlarged plan view of an essential part in FIG. 4 and a passive element having the passive type electrode structure on which a pixel circuit constituted of a thin film transistor for selecting and driving a pixel and a holding capacitance is not formed are integrally formed by the same manufacturing steps.

Further, the anodes AD and cathodes KD of these dummy pixels PD are respectively electrically connected with the anodes AD and the cathodes KD of the respective display pixels SP (organic light emitting element ELD) which are formed in the inside of the display region AR and are driven by passive driving. Here, these dummy pixels DP do not constitute the organic light emitting elements which are always driven after being turned on and hence, in this embodiment, the passive type electrode structure is used in view of the simplicity of the electrode structure, the cost and the like.

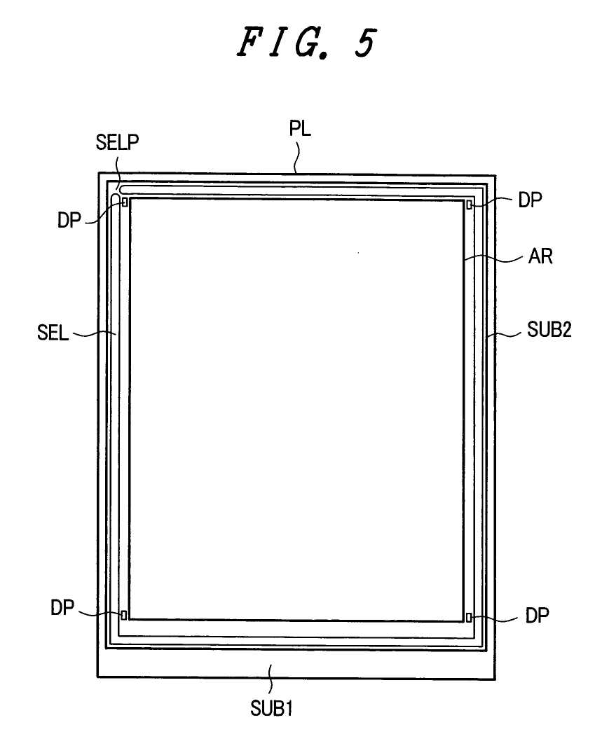

Further, a sealing material SEL is applied to respective peripheral portions of the light transmitting glass substrate SUB1 on which the large number of display pixels SP are formed and the sealing glass substrate SUB2 having a cap shape which laminates a desiccant DRY to an inner surface thereof in the dry nitrogen atmosphere of a dew point of approximately 90° C. and both substrates are laminated to face each other and are hermetically sealed to each other thus forming a package whereby the display panel is formed. Here, the sealing material SEL is applied in an open loop shape as shown in a plan view in FIG. 5 in a state that a leak path SELP having a width of approximately 0.1 mm is formed at a corner portion.

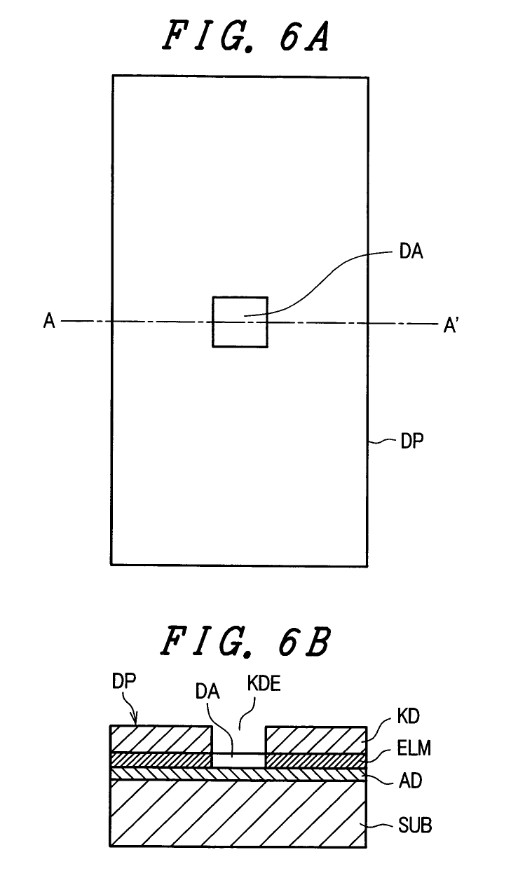

In the display panel having such a constitution, YAG laser beams (oscillation wavelength: 1064 nm) which are formed in a square shape of approximately 10 μm by an aperture are radiated to a substantially center portion of the cathode KD which is exposed on the surface of each dummy pixel DP from the outside of the sealing glass substrate SUB2 so as to remove the center portion of the cathode KD. Due to such an operation, as shown in a plan view in FIG. 6A and a cross-sectional view in FIG. 6B taken along a line A-A′ in FIG. 6A, a cathode non-forming portion KDE from which a portion of the cathode KD is removed is formed. Here, the laser output is approximately 1 GW/cm², a pulse width is approximately 10 ns and the number of shots is one shot. When a lighting inspection is performed on the dummy pixel DP by passive matrix driving after approximately 24 hours, a non-light-emitting area DA having a square shape of approximately 45 μm is observed at the center portion of the dummy pixel DP.

In such a constitution, when a leak portion is present in the sealing structure which is sealed by the sealing material SEL, in the organic multilayered film ELM of the organic light emitting element ELD, due to the intrusion of water molecules, the non-light emitting area DA which is four times to five times in size or approximately twenty times in area as large as the cathode non-forming portion KDE which is removed by the laser radiation is generated. That is, by inspecting the size of the non-light-emitting area DA of the cathode non-forming portion KDE, it is possible to easily determine the defective/non-defective condition of the sealing structure.

To explain in detail, in the above-mentioned constitution, a peripheral portion of the cathode non-forming portion KDE which is formed by removing a portion of the cathode KD in the dummy pixel DP is directly exposed to the atmosphere in the inside of the package. When the moisture concentration of the atmosphere in the inside of the package is sufficiently low, only the region where the cathode KD is not present becomes the non-light emitting area DA and a peripheral portion of the non-light emitting area DA of the cathode KD normally emits light.

Further, due to the cathode non-forming portion KDE which is formed by removing a portion of the cathode KD in the inside of the dummy pixel DP, the organic multi-layered ELM of the organic EL element ELD is exposed and is exposed to the atmosphere in the inside of the package. However, when the sealing structure of the package is complete, the moisture concentration of the atmosphere in the inside of the package is sufficiently low and hence, there is no possibility that the exposed organic multi-layered film ELM is degenerated. Accordingly, although the cathode non-forming portion KDE which is formed by removing a portion of the cathode KD becomes the non-light emitting area DA, there is no possibility that the peripheral portion of the cathode non-forming portion KDE also becomes non-light emitting area.

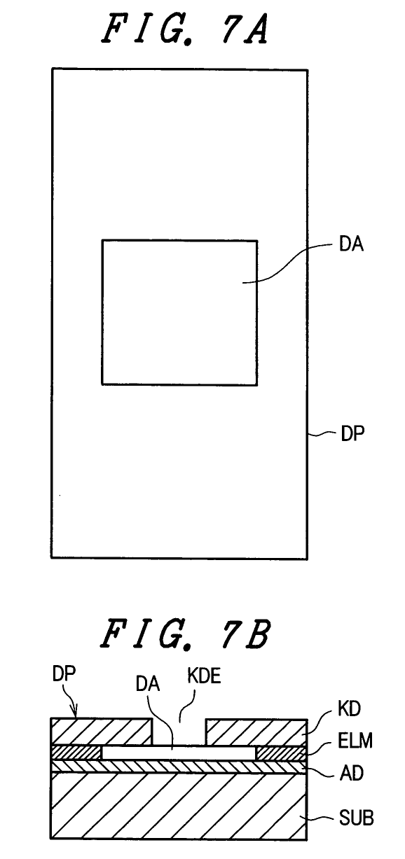

On the other hand, when the sealing structure of the package is incomplete, the moisture concentration of the atmosphere in the inside of the package is elevated and hence, the moisture diffuses in the in-plane direction and hence, the organic multi-layered film ELM on the peripheral portion of the cathode non-forming portion KDE is degenerated and does not emit light, wherein as respectively shown in a plan view in FIG. 7A and a cross-sectional view in FIG. 7B taken along a line A-A′ in FIG. 7A, the size of the non-light emitting area DA becomes larger than the size of the cathode non-forming portion KDE. Depending on the degree of incompleteness of the sealing structure, there may be a case that the non-light-emitting area DA is enlarged to the inside by several 10 μm. Accordingly, by comparing the size of the area of the cathode non-forming portion KDE and the size of the non-light-emitting area DA of the dummy pixel DP, it is possible to easily determine whether the package structure is defective or non-defective, that is, whether the moisture concentration in the inside of the package is defective or non-defective.

### Embodiment 2

Next, an embodiment 2 of the display device according to the present invention is explained in detail in conjunction with FIG. 2 to FIG. 7. In the same manner as the embodiment 1, with respect to an organic light emitting element ELD which constitutes an organic EL display device, on a display region AR formed on an active-matrix-type light transmitting glass substrate SUB1 having a pixel selection circuit (or a pixel drive circuit) which includes thin film transistors formed of a low-temperature polysilicon semiconductor films, anodes AD made of ITO (In—Ti—O), organic multilayered films ELM made of an organic material and cathodes KD made of lithium fluoride (LiF), aluminum (Al) or the like are formed by a vapor deposition method using a mask.

Further, at respective four corners outside the display region AR which is formed by arranging the large number of organic light emitting elements ELD in a matrix array on the main surface of the light transmitting glass substrate SUB1, dummy elements DP each of which is constituted of an organic light emitting element having the exactly same constitution as the organic light emitting element ELD as shown in an enlarged plan view of an essential part in FIG. 4 and a passive element having the passive type electrode structure on which a pixel circuit constituted of a thin film transistor for selecting and driving a pixel and a holding capacitance is not formed are integrally formed by the same manufacturing steps.

Further, a sealing material SEL is applied to respective peripheral portions of the light transmitting glass substrate SUB1 and the sealing glass substrate SUB2 which laminates a desiccant DRY to an inner surface thereof in the dry nitrogen atmosphere of a dew point of approximately 90° C. and both substrates are laminated to face each other and are hermetically sealed to each other thus forming a package whereby the display panel is formed. Here, the sealing material SEL is applied in an open loop shape as shown in FIG. 5 in a state that a leak path SELP having a width of approximately 0.1 mm is formed at a corner portion.

In the display panel having such a constitution, second harmonic waves (oscillation wavelength: 532 nm) of YAG laser beams which are formed in a rectangular shape of approximately 2×5 μm by an aperture are radiated to a substantially center portion of the cathode KD which is exposed on the surface of each dummy pixel DP so as to remove the center portion of the cathode KD. Due to such an operation, a cathode non-forming portion KDE from which a portion of the cathode KD is removed is formed. Here, the laser output is approximately 1 GW/cm², a pulse width is approximately 20 ns and the number of shots is one shot. When a lighting inspection is performed on the dummy pixel DP by passive matrix driving after approximately 24 hours, a non-light-emitting area DA having a rectangular shape of approximately 40×50 μm is observed at the center portion of the dummy pixel DP.

In such a constitution, when a leak portion is present in the sealing structure, the non-light emitting area DA which is approximately five times in the longitudinal size or approximately 200 times in area as large as the cathode non-forming portion KDE which is removed by the laser radiation is generated. That is, by inspecting the size of the non-light-emitting area DA of the cathode non-forming portion KDE, it is possible to easily determine whether the sealing structure is defective or non-defective.

### Embodiment 3

Next, an embodiment 3 of the display device according to the present invention is explained in detail in conjunction with FIG. 2 to FIG. 7. In the same manner as the embodiment 1, with respect to an organic light emitting element ELD which constitutes an organic EL display device, on a display region AR formed on an active-matrix-type light transmitting glass substrate SUB1 having a pixel selection circuit (or a pixel drive circuit) which includes thin film transistors formed of a low-temperature polysilicon semiconductor films, anodes AD made of ITO (In—Ti—O) as shown in an enlarged cross-sectional view in FIG. 3, organic multilayered films ELM made of an organic material and cathodes KD made of lithium fluoride (LiF), aluminum (Al) or the like are formed by a vapor deposition method using a mask.

Further, at respective four corners outside the display region AR which is formed by arranging the large number of organic light emitting elements ELD in a matrix array on the main surface of the light transmitting glass substrate SUB1, dummy elements DP each of which is constituted of an organic light emitting element having the exactly same constitution as the organic light emitting element ELD as shown in an enlarged plan view of an essential part in FIG. 4 and a passive element having the passive type electrode structure on which a pixel circuit constituted of a thin film transistor for selecting and driving a pixel and a holding capacitance is not formed are integrally formed by the same manufacturing steps.

Further, a sealing material SEL is applied to respective peripheral portions of the light transmitting glass substrate SUB1 and the sealing glass substrate SUB2 which laminates a desiccant DRY to an inner surface thereof in the dry nitrogen atmosphere of a dew point of approximately 90° C. and both substrates are laminated to face each other and are hermetically sealed to each other. Here, the sealing material SEL is applied in a closed loop shape such that the leak path SELP is not formed at the corner portion shown in FIG. 5.

In the display panel having such a constitution, YAG laser beams (oscillation wavelength: 1064 nm) which are formed in a square shape of approximately 10 μm by an aperture are radiated to a substantially center portion of the cathode KD which is exposed on the surface of each dummy pixel DP so as to remove the center portion of the cathode KD. Due to such an operation, a cathode non-forming portion KDE from which a portion of the cathode KD is removed is formed. Here, the laser output is approximately 1 GW/cm², a pulse width is approximately 10 ns and the number of shots is one shot. When a lighting inspection is performed on the dummy pixel DP, after approximately 24 hours, a non-light-emitting area DA having a square shape of approximately 10 μm is observed at the center portion of the dummy pixel DP.

In such a constitution, when a leak portion is not present in the sealing structure, the non-light emitting area DA which is approximately equal in size to the cathode non-forming portion KDE which is removed by the laser radiation is only generated. That is, by inspecting the size of the non-light-emitting area DA of the cathode non-forming portion KDE, it is possible to easily determine whether the sealing structure is defective or non-defective.

Here, in the above-mentioned respective embodiments, in view of the relationship that the dummy pixels DP are manufactured together with the display pixels SP which are formed in a large number in the inside of the display region AR using the same mask, the explanation is made with respect to the case in which the dummy pixels DP have the substantially equal shape. However, the present invention is not limited to such a case and the dummy pixels DP may be formed in various shapes and sizes depending on the necessity.

Further, in the above-mentioned respective embodiments, although the explanation has been made with respect to the case in which the positions where dummy pixels DP are arranged are set to four corners of the display region AR, the present invention is not limited to such a case and the dummy pixels DP may be arranged at desired positions depending on the necessity. However, to take the fact that the sealing defects of the sealing structure are liable to easily occur at corner portions of the display panel into consideration, it is preferable that the positions where the dummy pixels DP are arranged are positioned at the corner portions of the display panel and close to the display region AR. Further, although the number of the dummy pixels DP is not particularly limited, in view of the above-mentioned reason, it is desirable that one pixel is arranged at each corner portion.

Further, in the above-mentioned respective embodiments, as means for forming the cathode non-forming portion KDE in the dummy pixel DP, a method which forms and removes the portion of the cathode KD using the YAG laser beams after completion of the panel is used. However, the present invention is not limited to such a case and the kind of laser beams is not particularly limited. It is preferable to use YAG basic wave laser beams having a wavelength at which the organic EL material does not absorb laser energy. However, second harmonic waves of the YAG laser beams can be also used. Still further, pulse laser beams which do not apply a thermal damage to the organic EL material made of an organic material are preferable.

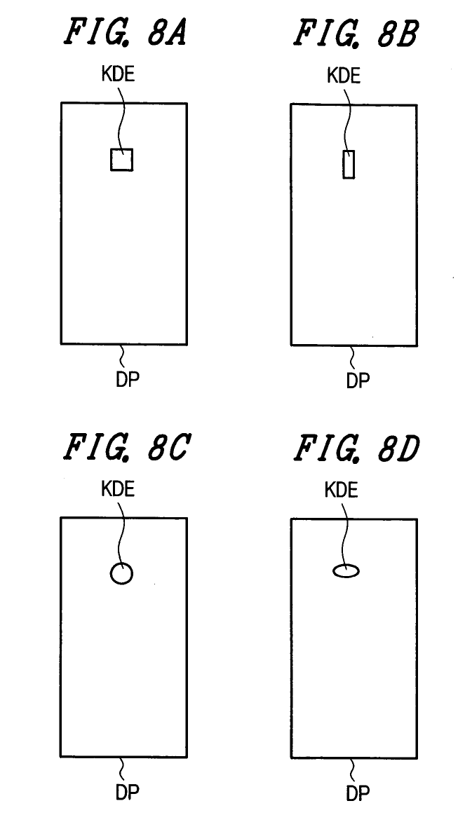

FIG. 8A to FIG. 8D are plan views of the dummy pixel DP for explaining another embodiment of the above-mentioned cathode non-forming portion KDE. A shape of the cathode non-forming portion KDE may be a square shape as shown in FIG. 8A or a rectangular shape as shown in FIG. 8B. Further, the shape of the cathode non-forming portion KDE may be a circular shape as shown in FIG. 8C or an elliptical shape as shown in FIG. 8D. However, in view of the easiness of forming the laser beam shape, it is preferable to set the shape of the cathode non-forming portion KDE into the rectangular shape including a square shape.

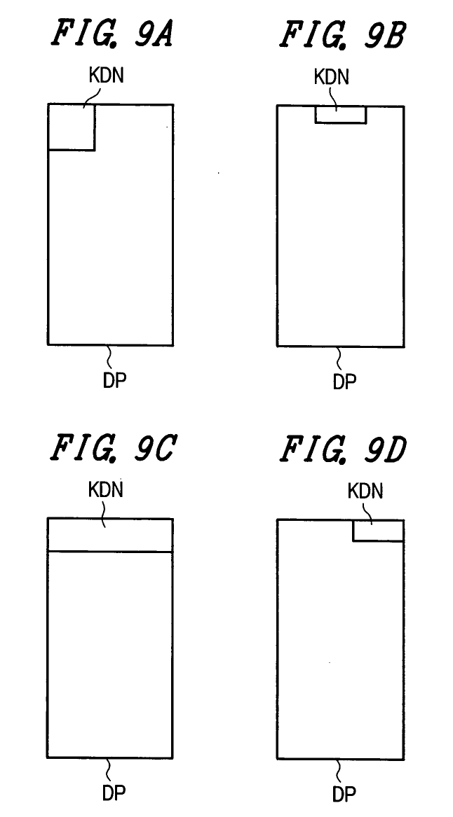

FIG. 9A to FIG. 9D are plan views of the dummy pixel DP for explaining another embodiment in which the dummy pixel DP is provided with an area where the cathode KD does not exist. In place of removing the portion of the cathode by radiating laser beams to one portion of the dummy pixel DP as mentioned above, it is possible to realize the area where the cathode KD is not present by forming an opened cathode non-forming portion KDE where a metal (lithium fluorite, aluminum) for forming the cathode KD is not vapor-deposited in a portion of the dummy pixel DP. The opened cathode non-forming portion KDE may be formed in a corner portion of the dummy pixel DP as shown in FIG. 9A, in a portion of a short side of the dummy pixel DP as shown in FIG. 9B, in a short side portion of the dummy pixel DP as shown in FIG. 9C or in any one of corner portions of the dummy pixel DP in FIG. 9D. Further, the opened cathode non-forming portion KDE may be formed in plural portions. In this embodiment, through the opened cathode non-forming portion KDE, a portion of the electron transport layer ETL which constitutes an uppermost-layer of the organic multilayered film ELM is exposed.

Further, although there is no problem provided that the opening area of the cathode non-forming portion KDE is not more than the pixel area, the opening area of the cathode non-forming portion KDE may preferably be within a range of 0.01% to 95% of the pixel area. When the opening area is less than 0.01%, the opening size of the cathode non-forming portion KDE becomes 1 μm square and hence, the determination inspection becomes difficult. Further, when the opening area exceeds 95%, it is difficult to compare the size of the cathode non-forming portion KDE and that of the non-light emitting area DA. Accordingly, it becomes apparent from an experiment which inventors of the present application carry out that the range of 0.01% to 95% of the pixel area is preferable.

Further, in the above-mentioned embodiments, the explanation is made with respect to the case in which the organic EL display device is used as the display device. However, it is needless to say that it is possible to obtain advantageous effects exactly same as the above-mentioned advantageous effects by applying the present invention to both of the high-molecular organic EL display device or the low-molecular organic EL display device.

Further, in the above-mentioned respective embodiments, the explanation is made with respect to the case in which the dummy pixel DP is formed by adopting the passive type electrode structure. However, it is needless to say that the present invention is not limited to such a structure and advantageous effects exactly same as the above-mentioned advantageous effects can be obtained by forming the dummy pixel DP by adopting the active type electrode structure.

Further, in the above-mentioned respective embodiments, the explanation is made with respect to the case in which the organic light emitting element having the active matrix type electrode structure is used in the display region AR as the organic EL display device. However, it is needless to say that the present invention is not limited to such a case and advantageous effects exactly same as the above-mentioned advantageous effects can be obtained by using the organic light emitting element having the passive matrix type electrode structure. Here, it is needless to say that, in this case, it is necessary to separately form the pixel circuit which is constituted of a large number of thin film transistors which constitute active elements for selecting and driving pixels and holding capacitances on the light transmitting glass substrate SUB1.

Here, it is needless to say that, to express the above-mentioned cathode non-forming portion KDE in other words, the cathode non-forming portion KDE is expressed as the region where the multilayered film formed on a portion of the region where the anode and the cathode are overlapped to each other is not overlapped to the cathode or the opening portion of the cathode which is formed on one part of the region where the anode and the cathode are overlapped.

1. An organic EL display device comprising;
a substrate and an organic EL elements formed on the substrate:
the organic EL elements comprising:
first electrodes which are formed on the substrate,
multilayered films including organic light emitting layer which are formed on the first electrodes, and
the second electrodes which are formed on the multilayered films,
the organic EL elements being hermetically sealed:
wherein a part of the organic EL elements, whose second electrode has an opening portion, is formed in the outside of the display region.

2. A organic EL display device according to claim 1,
wherein said the opening portion is within a range of 0.01% to 95% of a portion where one first electrode overlaps to one first electrode in a display area.

3. A organic EL display device according to claim 1,
wherein the opening portion is a rectangular shape.

4. A organic EL display device according to claims 3,
wherein the opening portion is formed by removing the portion with the radiation of YAG pulse laser beams.

5. A organic EL display device according to claim 1,
wherein the organic EL elements in a display area are driven by active matrix driving method and a organic EL element in the outside of the display area is driven by passive matrix driving method.

6. A organic EL display device according to claim 1,
wherein the organic EL elements in a display area and the organic EL element in the outside of the display area are individually driven.

7. A organic EL display device according to claim 1,
A display device according to claim 9, wherein a plurality of first pixels are driven by active matrix driving and the second pixel is driven by passive matrix driving.

8. A display device comprising:
a first substrate which has a display region formed of a pixel circuit in which a large number of first pixels each of which is constituted of a light emitting element and an active element are arranged in a matrix array on a main surface thereof; and
a second substrate which covers the main surface of the first substrate and is hermetically sealed to a peripheral portion of the first substrate with a sealing agent therebetween,
wherein at least one second pixel which is constituted of a light emitting element and a passive element is arranged outside the display region on the main surface of the first substrate,
the first pixels and the second pixel are formed by sequentially stacking a first electrode, a light emitting layer or a multilayered film including the light emitting layer and a second electrode on the main surface of the first substrate, and
in the second pixel, the multilayered film is exposed by removing at least a portion of the second electrode, and an electric current path is formed between a remaining portion of the second electrode and the first electrode.

9. A display device according to claim 8,
wherein an area removed by the removal of the portion of the second electrode is within a range of 0.01% to 95% of an area of the second electrode.

10. A display device according to claim 8,
wherein a shape which is formed after removing the portion of the second electrode has a rectangular shape.

11. A display device according to any one of claims 10,
wherein a portion which is formed by removing the portion of the second electrode is made to have a shape which is formed by removing the portion with the radiation of YAG pulse laser beams.

12. A display device according to claim 8,
wherein a portion which is formed by removing the portion of the second electrode is formed into a second electrode non-forming portion.

13. A display device according to any one of claims 8, wherein a plurality of first pixels and second pixel are individually driven.

14. A display device according to claim 8, wherein a plurality of first pixels are driven by active matrix driving and the second pixel is driven by passive matrix driving.
